(19) United States
(12) Patent Application Publication
(10) Pub. No.: US 2011/0211410 A1
(43) Pub. Date: Sep. 1, 2011

(54) SEMICONDUCTOR MEMORY DEVICE

(76) Inventor: Seung-Lo KIM, Gyeonggi-do (KR)

(21) Appl. No.: 12/753,606

(22) Filed: Apr. 2, 2010

(30) Foreign Application Priority Data
Feb. 26, 2010 (KR) 10-2010-0018007

(51) Int. Cl. G11C 7/06

(52) U.S. Cl. 365/210.1

(57) ABSTRACT

A semiconductor memory device having an open bit line structure includes a normal memory cell block, a reference memory cell block, and a sense amplifier. The normal memory cell block includes a plurality of normal memory cells and a driving bit line connected to the normal memory cells. The reference memory cell block includes a reference bit line connected to a reference cell capacitor. The sense amplifier is configured to sense and amplify voltage levels of the driving bit line and the reference bit line.

### CROSS-REFERENCE TO RELATED APPLICATIONS

The present application claims priority of Korean Patent Application No. 10-2010-0018007, filed on Feb. 26, 2010, which is incorporated herein by reference in its entirety.

### BACKGROUND OF THE INVENTION

Exemplary embodiments of the present invention relate to semiconductor design technology, and more particularly, to a semiconductor memory device having an open bit line structure.

In general, a semiconductor memory device, such as a double data rate synchronous dynamic random access memory (DDR SDRAM), includes a large number of memory cells. As the integration density of a semiconductor memory device increases exponentially, the number of memory cells also increases. Such memory cells are regularly arranged to constitute memory cell arrays, which are arranged to form a memory cell block.

The memory cell structure of the semiconductor memory device may be largely classified into a folded bit line structure and an open bit line structure. The difference between the folded bit line structure and the open bit line structure is described below.

A semiconductor memory device having a folded bit line structure includes a bit line configured to drive data (hereinafter, referred to as a driving bit line) and a bit line configured to serve as a reference line during an amplification operation (hereinafter, referred to as a reference bit line), both of which are disposed in the same memory cell block coupled to a bit line sense amplifier disposed in a core region of the semiconductor memory device. Therefore, the driving bit line and the reference bit line undergo the same noise, which counterbalance each other. Such a counterbalancing of the folded bit line structure guarantees stable operations that are robust against noise. On the other hand, a semiconductor memory device having the open bit line structure includes a driving bit line and a reference bit line disposed in different memory cell blocks. Therefore, noise occurring in the driving bit line is different from noise occurring in the reference bit line, making the open bit line structure vulnerable to noise.

In the case of the folded bit line structure, the unit memory cell structure has an 8F2 design, and in the case of the open bit line structure, the unit memory cell structure has a 6F2 design. The unit memory cell structure is one factor contributing to the size of a semiconductor memory device. Therefore, assuming the same data storage capacity, semiconductor memory devices having the open bit line structure can be designed in less space than those having the folded bit line structure.

FIG. 1 is a circuit diagram of a semiconductor memory device having a known folded bit line structure.

Referring to FIG. 1, the semiconductor memory device having a folded bit line structure includes first and second memory cell blocks 110 and 120 and a sense amplifier 130.

Each of the first and second memory cell blocks 110 and 120 includes a plurality of memory cell arrays which store data. The first memory cell block 110 is provided with a first bit line BLT1 and a first bit-bar line BLB1, and the second memory cell block 120 is provided with a second bit line BLT2 and a second bit-bar line BLB2.

The sense amplifier 130 senses and amplifies the voltage levels of the first bit line BLT1 and the first bit-bar line BLB1 or the voltage levels of the second bit line BLT2 and the second bit-bar line BLB2 in response to first and second bit line separation signals BISH and BISL. The sense amplifier 130 includes transistors configured to be turned on in response to the first and second bit line separation signals BISH and BISL, and a latch-type sense amplification circuit configured to perform a sense amplification operation.

As described above, the semiconductor memory device having the folded bit line structure includes a driving bit line and a reference bit line disposed in the same memory cell block. For example, when the first bit line separation signal BISH is activated to a logic high level and the second bit line separation signal BISL is deactivated to a logic low level, data is transferred to the first bit line BLT1 or the first bit-bar line BLB1 according to an activated word line WL. In this case, the bit line through which the data is transferred serves as the driving bit line, and its complementary bit line serves as the reference bit line. The sense amplification circuit of the sense amplifier 130 senses the data transferred through the first bit line BLT1 or the first bit-bar line BLB1, and amplifies the sensed data to a voltage level corresponding to a pull-up voltage RTO or a pull-down voltage SB, which are applied to the sense amplification circuit as power supply voltages.

FIG. 2 is a circuit diagram of a semiconductor memory device having a known open bit line structure.

Referring to FIG. 2, the semiconductor memory device having the open bit line structure includes first and second memory cell blocks 210 and 220 and a sense amplifier 230.

Each of the first and second memory cell blocks 210 and 220 includes a plurality of memory cell arrays which store data. The first memory cell block 210 is provided with a first bit line BLT1, and the second memory cell block 220 is provided with a first bit-bar line BLB1.

The sense amplifier 230 senses and amplifies the voltage levels of the first bit line BLT1 and the first bit-bar line BLB1, and has the substantially same configuration as the sense amplification circuit of FIG. 1.

As described above, the semiconductor memory device having the open bit line structure includes a driving bit line disposed in one memory cell block, and a reference bit line disposed in another memory cell block. For example, where data is driven to the first bit line BLT1, the first bit-bar line BLB1 disposed in the second memory cell block 220 serves as the reference bit line. On the contrary, where data is driven to the first bit-bar line BLB1, the first bit line BLT1 disposed in the first memory cell block 210 serves as the reference bit line.

Thus, the semiconductor memory device having the open bit line structure does not require additional transistors to separate the sense amplifier 230 from the first memory cell block 210 and the second memory cell block 220. Accordingly, the sense amplifier 230 only has to sense and amplify the voltage levels of the first bit line BLT1 and the first bit-bar line BLB1 according to the activated word line WL.

FIG. 3 illustrates a portion of a semiconductor memory device having an open bit line structure.

Referring to FIG. 3, the semiconductor memory device includes a first memory cell block 310, a plurality of drivers 320 configured to activate word lines WL disposed in the first memory cell block 310, a second memory cell block 330, a plurality of second drivers 340 configured to activate word lines WL disposed in the second memory cell block 330, and first and second groups of sense amplifiers 350 and 360 disposed between the memory cell blocks. Although not illustrated in FIG. 3, a third memory cell block having substantially the same configuration as the first memory cell block 310 is disposed under the second memory cell block 330. As shown in FIG. 3, the first memory cell block 310 and the second memory cell block 330 share the first group of sense amplifiers 350. More specifically, each sense amplifier belonging to the first group of sense amplifiers 350 can sense and amplify data transferred through the bit line and bit-bar line from both the first memory cell block 310 and the second memory cell block 320. Likewise, the second memory cell block 330 and the third memory cell block (not shown) share the second group of sense amplifiers 360, which sense and amplify data transferred through corresponding bit lines.

For sake of convenience, only an operation of the first group of sense amplifiers 350 disposed between the first memory cell block 310 and the second memory cell block 330 is described in more detail below.

For example, when an operation is performed to transfer data to the bit line A, disposed in the first memory cell block 310 and is connected to one of the sense amplifiers belonging to the first group of sense amplifiers 350, the bit line B, disposed in the second memory cell block 330 and connected to the same sense amplifier belonging to the first group of sense amplifiers 350 serves as the reference bit line. In this case, the second drivers 340, which control the word lines WL of the second memory cell block 330, deactivate all the corresponding word lines WL. Thus, only the capacitance of the bit line B itself influences the voltage level of the bit line B serving as the reference bit line. Subsequently, the sense amplifier belonging to the first group of sense amplifiers 350 senses and amplifies the data transferred through the bit line A and the voltage level of the bit line B.

Such a sense and amplification operation is similarly performed when the bit line A serves as the reference bit line. Therefore, it is desired that the bit line A disposed in the first memory cell block 310 and the bit line B disposed in the second memory cell block 330 have the same capacitance when they are used as the reference bit line. Consequently, the lengths of the two bit lines should be approximately equal to each other.

Meanwhile, assuming that the first memory cell block 310 is disposed at an edge of the plurality of memory cell blocks, bit lines of the memory cells in the first memory cell block 310, which are not connected to the first group of sense amplifiers 350, are not used. Further, as the size of the memory cell array increases, the lengths of the unused bit lines in the first memory cell block 310 also increases. Therefore, these unused bit lines may contribute to an increase in the net die loss of the semiconductor memory device.

### SUMMARY OF THE INVENTION

Exemplary embodiments of the present invention are directed to a semiconductor memory device which is capable of increasing capacitance influencing a reference bit line by using a reference cell capacitor.

In accordance with an embodiment of the present invention, a semiconductor memory device having an open bit line structure includes a normal memory cell block including a plurality of normal memory cells and a driving bit line connected to the normal memory cells, a reference memory cell block including a reference bit line connected to a reference cell capacitor, and a sense amplifier configured to sense and amplify voltage levels of the driving bit line and the reference bit line.

In accordance with another embodiment of the present invention, a semiconductor memory device having an open bit line structure includes a plurality of normal memory cell blocks each including a plurality of normal memory cells and a driving bit line connected to the normal memory cells, first and second reference memory cell blocks disposed at opposite sides of the plurality of normal memory cell blocks, which are coupled in series, and each including reference bit lines connected to reference cell capacitors, and first and second sense amplifiers configured to sense and amplify voltage levels of the driving bit lines and voltage levels of reference bit lines.

In accordance with yet another embodiment of the present invention, a semiconductor memory device includes a plurality of normal memory cell blocks having an open bit line structure and including a plurality of memory cells, and bit lines and bit-bar lines connected to the memory cells, a reference memory cell block including reference bit lines connected to a plurality of reference memory cells, and a plurality of drivers configured to apply an activation voltage to the plurality of reference memory cells so that capacitances of reference cell capacitors included in the reference memory cells influence the voltage levels of the reference bit lines.

In accordance with still another embodiment of the present invention, a semiconductor memory device includes a plurality of normal memory cell blocks having an open bit line structure and including a plurality of memory cells and bit lines and bit-bar lines connected to the memory cells, and a reference memory cell block including reference bit lines connected to a plurality of reference memory cells, wherein the reference bit lines are physically connected to reference cell capacitors included in the reference memory cells.

### BRIEF DESCRIPTION OF THE DRAWINGS

FIG. 1 is a circuit diagram of a semiconductor memory device having a known folded bit line structure.

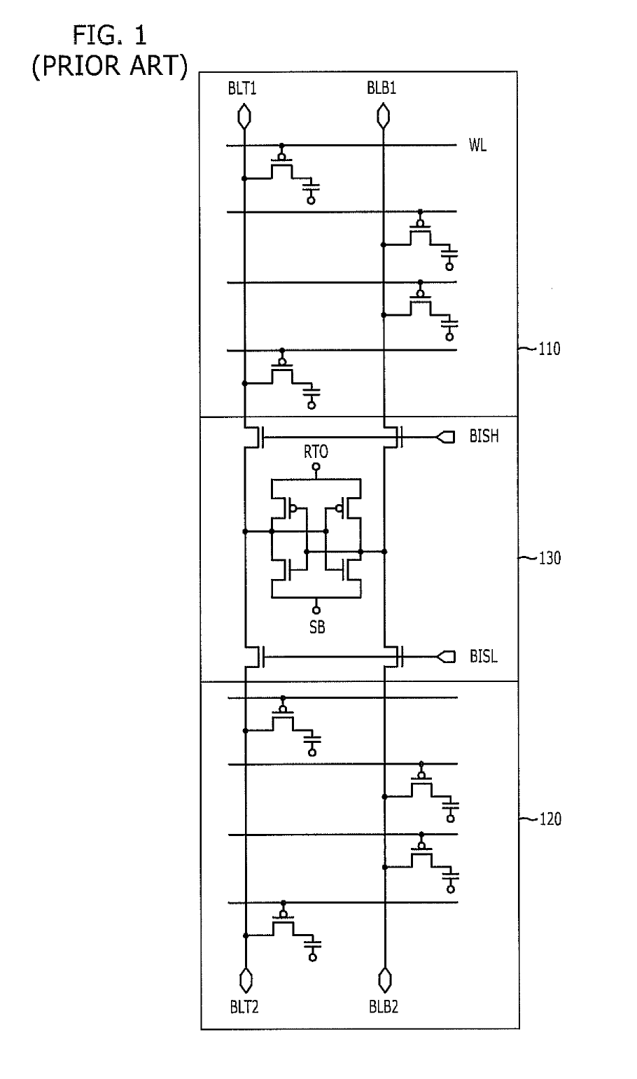

FIG. 2 is a circuit diagram of a semiconductor memory device having a known open bit line structure.

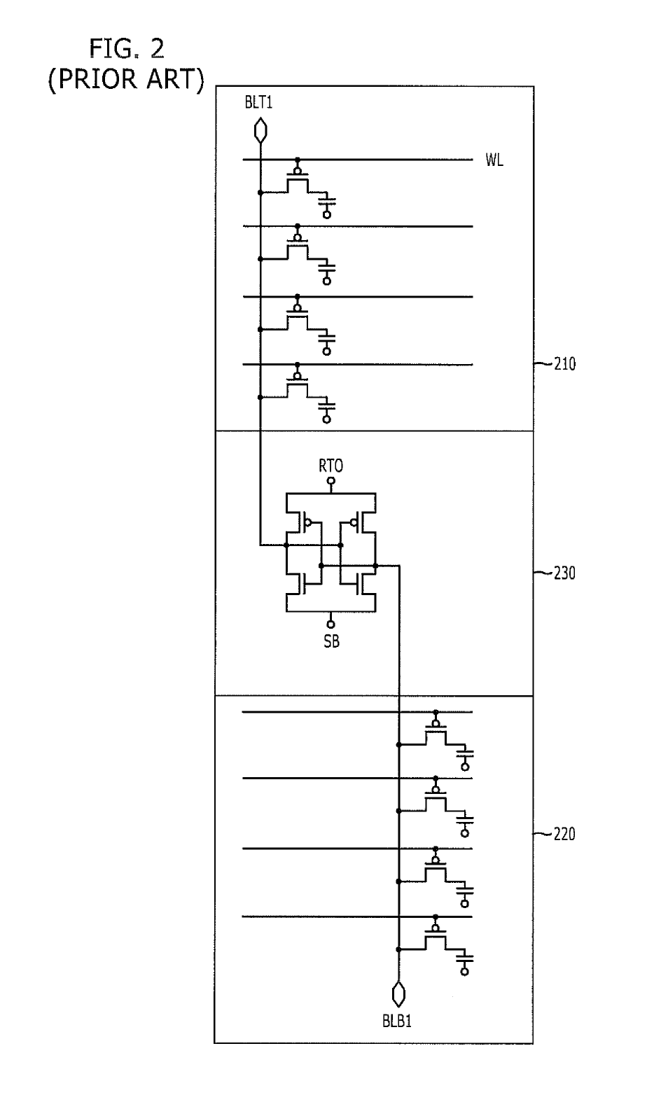

FIG. 3 illustrates a portion of a semiconductor memory device having an open bit line structure.

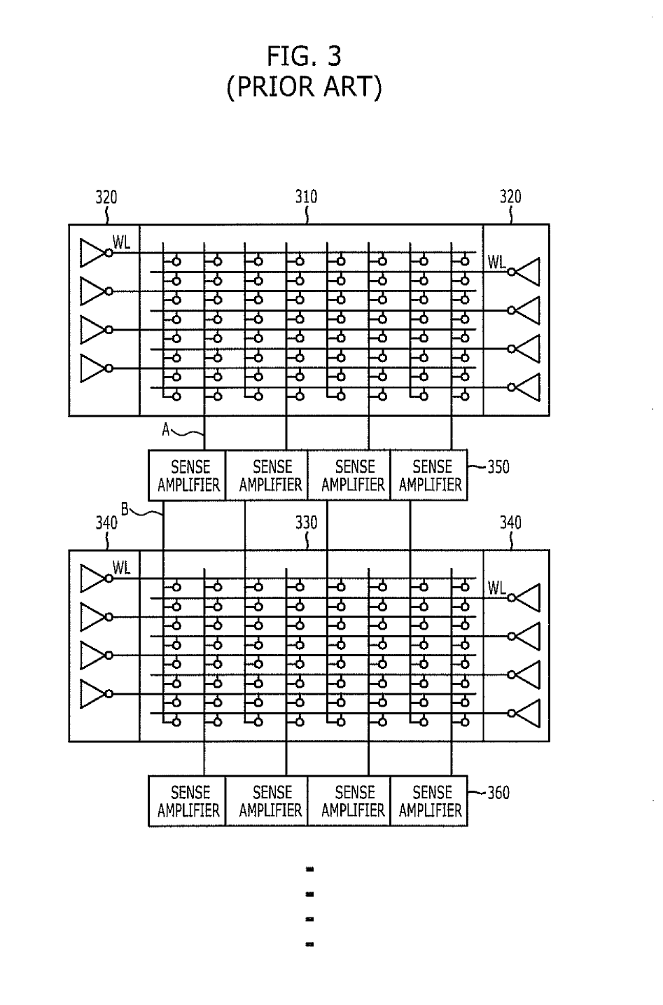

FIG. 4 illustrates a portion of a semiconductor memory device having an open bit line structure in accordance with a first embodiment of the present invention.

FIG. 5 is a circuit diagram illustrating an exemplary configuration of a reference memory cell of FIG. 4.

FIG. 6 illustrates a portion of a semiconductor memory device having an open bit line structure in accordance with a second embodiment of the present invention.

FIG. 7 is a circuit diagram illustrating an exemplary configuration of a reference memory cell of FIG. 4.

### DESCRIPTION OF SPECIFIC EMBODIMENTS

Exemplary embodiments of the present invention will be described below in more detail with reference to the accompanying drawings. The present invention may, however, be embodied in different forms and should not be construed as limited to the embodiments set forth herein. Rather, these embodiments are provided so that this disclosure will be thorough and complete, and will fully convey the scope of the present invention to those skilled in the art. Throughout the disclosure, like reference numerals refer to like parts throughout the various figures and embodiments of the present invention.

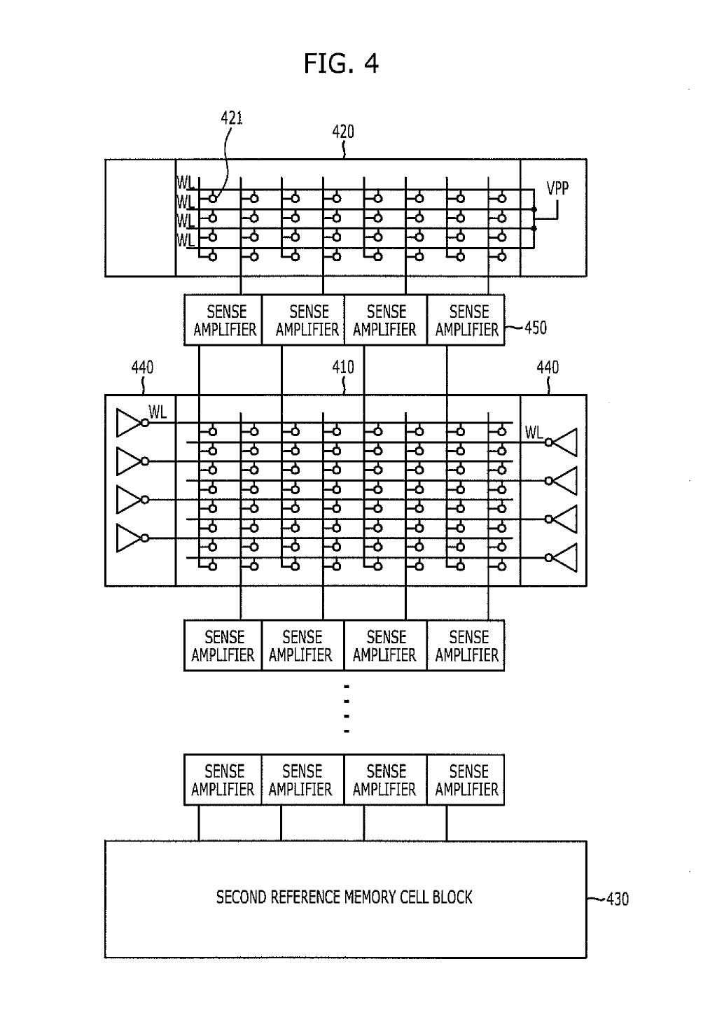

FIG. 4 illustrates a portion of a semiconductor memory device having an open bit line structure in accordance with a first embodiment of the present invention. For convenience, only one normal memory cell block 410 among a plurality of normal memory cell blocks belonging to the semiconductor device is illustrated. Although not shown in FIG. 4, the plurality of normal memory cell blocks are disposed between a first reference memory cell block 420 and a second reference memory cell block 430. More specifically, the plurality of normal memory cell blocks, the first reference memory cell block 420, and the second reference memory cell block 430 are coupled in series, where the first reference memory cell block 420 and the second reference memory cell block 430 are at opposite ends of the series of memory cell blocks. For example, where the plurality of normal memory cell blocks are disposed in a plane, the first reference memory cell block 420 and the second reference memory cell block 430 may be disposed at opposite edges of the plane.

Referring to FIG. 4, the semiconductor memory device includes a normal memory cell block 410, first and second reference memory cell blocks 420 and 430, a plurality of drivers 440, and a plurality of sense amplifiers 450. A plurality of normal memory cells and bit lines and bit-bar lines connected to the normal memory cells are disposed in the normal memory cell block 410. Further, a plurality of reference cell capacitors and reference bit lines connected to the reference cell capacitors are disposed in the first and second reference memory cell blocks 420 and 430. The plurality of drivers 440 are configured to activate word lines WL disposed in the normal memory cell block 410. The plurality of sense amplifiers 450 are disposed between the normal memory cell block 410 and the first reference memory cell block 420, and configured to perform a sense and amplification operation. The sense amplifiers 450 are connected to the bit lines disposed in the normal memory cell block 410 and the reference bit lines disposed in the first reference memory cell block 420. More specifically, each sense amplifier from among the plurality of sense amplifiers 450 is connected to one reference bit line disposed in the first reference memory cell block 420 and one bit line disposed in the normal memory cell block 410.

The semiconductor memory device in accordance with the embodiment of the present invention is characterized in that it includes the first and second reference memory cell blocks 420 and 430. The reference bit lines are disposed in the first and second reference memory cell blocks 420 and 430, and capacitances of reference cell capacitors, as well as, the capacitances of the reference bit lines themselves influence the voltage levels of the reference bit lines. Hence, even though the lengths of the reference bit lines are shorter than the lengths of the bit lines disposed in the normal memory cell block 410, the same capacitance influences the voltage level of the reference bit lines and the bit lines disposed in the normal memory cell block 410. In other words, the reference bit lines disposed in the first reference memory cell block 420 are connected to the reference memory cells 421, which include reference cell capacitors that provide an additional capacitance to compensate for the shorter length of the reference bit lines.

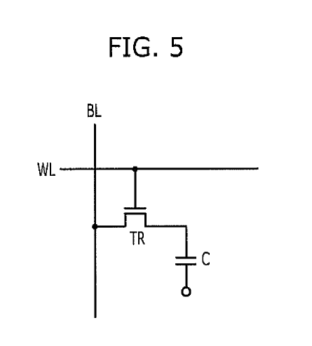

FIG. 5 is a circuit diagram illustrating an exemplary configuration of the reference memory cell 421 of FIG. 4.

Referring to FIG. 5, the reference memory cell 421 includes a reference cell capacitor C configured to add its capacitance to the reference bit line BL, and a reference cell transistor TR configured to electrically connect the reference cell capacitor C to the reference bit line BL in response to an activation voltage applied to the word line WL. The reference cell transistor TR forms a source-drain path between the reference bit line BL and the reference cell capacitor C and has a gate connected to the word line WL.

In the semiconductor memory device in accordance with the embodiment of the present invention, the capacitance of the reference cell capacitor C may influence the voltage level of the reference bit line BL, and thus, it is possible to sufficiently ensure the capacitance influencing the voltage level of the reference bit line BL, even though the length of the reference bit line BL is shortened. In FIG. 5, when the reference cell transistor TR is turned on, the capacitance of the reference cell capacitor C influences the voltage level of the reference bit line BL.

Referring again to FIG. 4, the semiconductor memory device in accordance with the embodiment of the present invention may use a pumping voltage (VPP) as an activation voltage for activating a reference memory cell, and may include a driver (not shown) configured to apply the pumping voltage (VPP) to a corresponding reference memory cell.

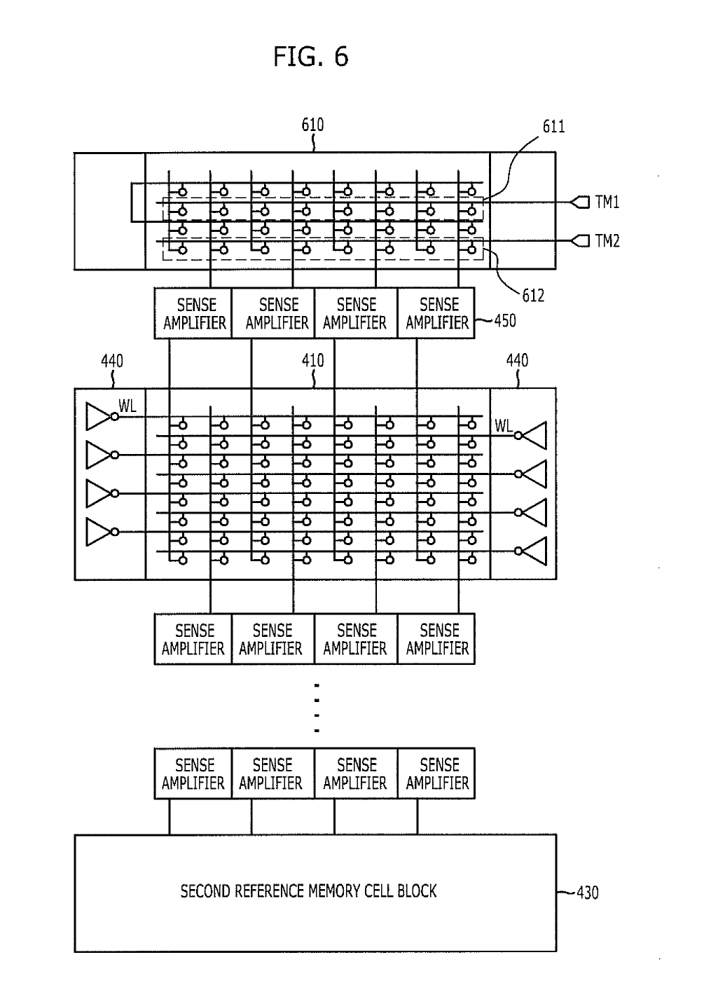

FIG. 6 illustrates a portion of a semiconductor memory device having an open bit line structure in accordance with a second embodiment of the present invention. Compared with the first embodiment shown in FIG. 4, the configuration of the first and second reference memory cell blocks is modified. For convenience, reference numeral ‘610’ is assigned to the first reference memory cell block, which is described below as a representative example.

Referring to FIGS. 5 and 6, the first reference memory cell block 610 of the semiconductor memory device includes a plurality of reference memory cells having the configuration of FIG. 5, and the plurality of reference memory cells are controlled by first and second test signals TM1 and TM2. First and second drivers (not shown) configured to generate the first and second test signals TM1 and TM2 are provided to adjust the capacitances that influence the voltage levels of the reference bit lines BL. The first driver may drive the first test signal TM1 to provide an activation voltage for turning on a corresponding reference memory cell. Further, the first driver may be configured to apply the first test signal TM1 to a first group of reference memory cells 611 among the plurality of reference memory cells. Meanwhile, the second driver may drive the second test signal TM2 to provide an activation voltage for turning on a corresponding reference memory cell. Further, the second driver may be configured to apply the second test signal TM2 to a second group of reference memory cells 612 among the plurality of reference memory cells.

Like the first embodiment of the present invention, the semiconductor memory device in accordance with the second embodiment of the present invention uses the capacitance of the cell capacitor C to influence the voltage level of the reference bit line BL. However, in addition, the second embodiment of the present invention allows the capacitance influencing the voltage level of the reference bit line BL to be adjusted by selectively driving the first and second test signals TM1 and TM2 to an activation voltage for corresponding reference memory cells.

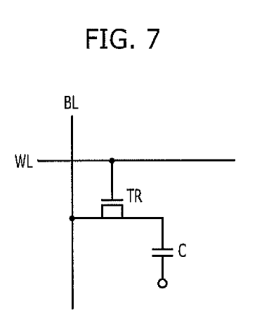

FIG. 7 is a circuit diagram illustrating another exemplary configuration of the reference memory cell 421 of FIG. 4. As will be described later, the reference memory cell shown in FIG. 7 requires no additional driver for supplying the activation voltage.

Referring to FIG. 7, the reference memory cell 421 includes a reference cell capacitor C configured to add its capacitance to the reference bit line BL, and a reference cell transistor TR connected to the word line WL. Moreover, the reference bit line BL and the . reference cell capacitor C are physically connected together. Thus, the capacitance of the reference cell capacitor C influences the reference bit line BL. Therefore, even though the reference memory cell 421 of FIG. 4 is implemented as illustrated in FIG. 7, the capacitance of the reference cell capacitor C may be added to the reference bit line BL. Accordingly, the length of the reference bit line BL may be reduced.

As described above, the semiconductor memory device in accordance with the embodiment of the present invention has the same capacitance influencing a reference bit line as that influencing a driving bit line coupled to the same sense amplifier, even though the reference bit lines are shorter than the driving bit lines. The ability to shorten reference bit lines means that the size of the memory cell array of the present invention may be smaller than that of the known open bit line structure. Accordingly, the net die may be increased when the present invention is adopted.

In other words, by reducing the length of the reference bit line, the net die loss of the semiconductor memory device may be reduced.

In accordance with the exemplary embodiments of the present invention, the net die loss of the semiconductor memory device may be reduced by decreasing the length of the reference bit line.

While the present invention has been described with respect to the specific embodiments, it will be apparent to those skilled in the art that various changes and modifications may be made without departing from the spirit and scope of the invention as defined in the following claims.

Moreover, the positions and types of logic gates and transistors set forth above may be modified according to the polarities of the input signals.

What is claimed is:

1. A semiconductor memory device having an open bit line structure, comprising:
a normal memory cell block comprising a plurality of normal memory cells and a driving bit line connected to the normal memory cells;
a reference memory cell block comprising a reference bit line connected to a reference cell capacitor; and
a sense amplifier configured to sense and amplify voltage levels of the driving bit line and the reference bit line.

2. The semiconductor memory device of claim 1, wherein a length of the reference bit line is shorter than a length of the driving bit line.

3. A semiconductor memory device having an open bit line structure, comprising:
a plurality of normal memory cell blocks each comprising a plurality of normal memory cells and a driving bit line connected to the normal memory cells;
first and second reference memory cell blocks disposed at opposite ends of the plurality of normal memory cell blocks, which are coupled in series, and each comprising reference bit lines connected to reference cell capacitors; and
first and second sense amplifiers configured to sense and amplify voltage levels of the driving bit lines and voltage levels of reference bit lines.

4. The semiconductor memory device of claim 3, wherein the first sense amplifier is disposed between the first reference memory cell block and one end of the plurality of normal memory cell blocks, and the second sense amplifier is disposed between the second reference memory cell block and the opposite end of the plurality of normal memory cell blocks.

5. The semiconductor memory device of claim 3, wherein a length of the reference bit lines is shorter than a length of the driving bit lines.

6. A semiconductor memory device comprising:
a plurality of normal memory cell blocks having an open bit line structure and comprising a plurality of memory cells, and bit lines and bit-bar lines connected to the memory cells;
a reference memory cell block comprising reference bit lines connected to a plurality of reference memory cells; and
a plurality of drivers configured to apply an activation voltage to the plurality of reference memory cells so that capacitances of reference cell capacitors included in the reference memory cells influence the voltage levels of the reference bit lines.

7. The semiconductor memory device of claim 6, further comprising a sense amplifier configured to sense and amplify voltage levels of one of the bit lines and one of the reference bit lines.

8. The semiconductor memory device of claim 6, wherein the activation voltage comprises a pumping voltage.

9. The semiconductor memory device of claim 6, wherein each of the reference cell capacitors and one of the reference bit lines are electrically connected together by the plurality of drivers.

10. The semiconductor memory device of claim 6, wherein each of the reference memory cells comprises:
a reference cell capacitor configured to add a capacitance thereof to a corresponding reference bit line among the reference bit lines; and
a cell transistor configured to form a source-drain path between the corresponding reference bit line and the reference cell capacitor, and receive the activation voltage at a gate thereof.

11. The semiconductor memory device of claim 6, wherein the plurality of drivers are configured to adjust the capacitances influencing the reference bit lines.

12. The semiconductor memory device of claim 6, wherein the plurality of drivers comprise:
a first driver configured to apply the activation voltage to a first group of the plurality of reference memory cells; and
a second driver configured to apply the activation voltage to a second group of the plurality of reference memory cells.

13. The semiconductor memory device of claim 6, wherein a length of the reference bit lines is shorter than a length of the bit lines.

14. A semiconductor memory device comprising:
a plurality of normal memory cell blocks having an open bit line structure and comprising a plurality of memory cells and bit lines and bit-bar lines connected to the memory cells; and
a reference memory cell block comprising reference bit lines connected to a plurality of reference memory cells,
wherein the reference bit lines are physically connected to reference cell capacitors included in the reference memory cells.

15. The semiconductor memory device of claim 14, wherein a length of the reference bit line is shorter than a length of the bit lines.

16. The semiconductor memory device of claim 14, further comprising a sense amplifier configured to sense and amplify voltage levels of one of the bit lines and one of the reference bit lines.
